(19) United States
(12) Patent Application Publication
(10) Pub. No.: US 2003/0109133 A1
(43) Pub. Date: Jun. 12, 2003

(54) Process for fabricating an electronic component incorporating an inductive microcomponent

(75) Inventors: Lionel Girardie, Eybens (FR); Jean-Baptiste David, Saint Martin D'Heres (FR)

Correspondence Address: HESLIN ROTHENBERG FARLEY & MESITI PC, 5 COLUMBIA CIRCLE, ALBANY, NY, 12203, US

(73) Assignee: MEMSCAP (Societe Anonyme) Parc Technologique des Fontaines Bernin, Crolles (FR)

(21) Appl. No.: 10/303,627

(22) Filed: Nov. 25, 2002

(30) Foreign Application Priority Data
Dec. 11, 2001 (FR) 01.15960

(51) Int. Cl. H01L 21/4763; H01L 23/48

(52) U.S. Cl. 438/638; 438/618; 257/758

(57) ABSTRACT

The invention relates to a process for fabricating electronic components, incorporating an inductive microcomponent placed on top of a substrate.

Such a component comprises:

at least one superposition of a layer (10, 10a) of material having a low relative permittivity and of a hard mask layer, the first layer (10) of material having a low relative permittivity resting on the upper face of the substrate (1);

a number of defined metal turns (39) on top of the superposition of layers (10, 10a) of material having a low relative permittivity; and

a copper diffusion barrier layer (35) present on the lower and lateral faces of the metal turns (39).

### TECHNICAL FIELD

The invention relates to the microelectronics field. More specifically, it relates to a process for producing inductive microcomponents on a substrate, which may itself incorporate an integrated circuit.

These components may especially be used in radiofrequency-type applications, for example in the telecommunications field.

The invention relates more specifically to a process for obtaining circuits having markedly higher performance characteristics than existing components, especially as regards the quality factor. The process forming the subject-matter of the invention also limits the number of steps needed to produce such components and ensures good reproducibility of the characteristics of the components that it allows to be manufactured.

### PRIOR ART

In document FR 2 791 470, the Applicant discloses a manufacturing process for producing microinductors or microtransformers on top of a substrate, and especially on top of an integrated circuit. In short, this process consists in depositing a layer of material having a low relative permittivity and then in etching this material at an aperture made in a hard mask, vertically in line with a contact for connection to the rest of the integrated circuit, so as to define an interconnection hole, also called a “via”.

After having deposited a resin on top of the hard mask, this resin is etched to form the channels defining the geometry of the turns of the inductive component. The process then continues with electrolytic copper deposition on top of the connection contact and in the channels defined in the upper resin.

Such a process has a number of drawbacks, among which may essentially be noted the fact that the electrolytic deposition step both forms the turns of the inductive component and fills the via, making contact with the metal contact connected to the integrated circuit. Since these regions are of different depths, it follows that the electrolytic deposition takes place differently at the turns and at the via. Certain irregularities are thus observed in the formation of the turns, irregularities which may prejudice the correct uniformity of electrical performance of the inductive component.

Furthermore, during the step of etching the upper resin it is necessary to etch longer at the via compared with the regions in which the channels intended to receive the turns are formed. This difference in etch depth releases chemical compounds at the bottom of the via, thereby disturbing the subsequent electrolytic copper deposition operation.

Moreover, the distance separating the inductive component from the substrate is substantially the same as the thickness of the layer of material of low relative permittivity. Given that it is not possible to increase the thickness of this layer very substantially, it will be appreciated that it is impossible to reduce the parasitic capacitance between the inductive component and the substrate below a value which depends on the way the process is carried out.

One of the objectives of the invention is to alleviate these various drawbacks and especially to allow the production of components which have dimensional characteristics as precise as possible so as to give the optimum electrical performance and thus increase the integration of components by reducing their size.

### SUMMARY OF THE INVENTION

The invention therefore relates to a process for fabricating an electronic component. Such a component incorporates an inductive microcomponent, such as an inductor or a transformer, which is placed on top of a substrate and is connected by at least one metal contact to this substrate.

In accordance with the invention, this process is characterized in that it comprises the following steps:

a) depositing on the substrate at least one stack of a layer of a material having a low relative permittivity and of a layer forming a hard mask;

b) making an aperture in the hard mask placed in the upper position, vertically in line with the metal contacts;

c) etching the layer or layers of material having a low relative permittivity and the subjacent hard mask layer or layers down to the metal contact, in order to form a via;

d) depositing a layer forming a copper diffusion barrier;

e) depositing a copper initiating layer;

f) depositing , electrolytically, a copper layer filling the via and covering the initiating layer;

g) planarizing the upper face until the hard mark layer, lying in the upper position, is exposed;

h) depositing an upper resin layer formed from a material having a low relative permittivity;

i) etching the upper resin layer in order to form the channels defining the turns of the inductive microcomponent and of possible other conducting features;

j) depositing a copper diffusion barrier layer;

k) depositing a copper initiating layer;

l) depositing copper electrolytically at least on top of the channels thus etched; and

m) planarizing until the upper resin layer is revealed.

Thus, the process according to the invention links up a number of steps which provide certain improvements over the processes of the prior art.

In particular, it will be noted that the process can link up the deposition of several layers of material having a low relative permittivity, each layer being separated by an intermediate layer, so that the distance separating the inductive component from the substrate is very greatly increased. The parasitic capacitance between the inductive component and the substrate is therefore greatly reduced, thereby greatly improving the performance of this inductive component, and especially its quality factor. In point of fact, at least two, three, or even four or five layers of material having a low relative permittivity, each having a thickness of the order of tens of microns, may be stacked up, thereby allowing the inductive component to be separated from the substrate by a distance of the order of or greater than 50 microns. This value should be compared with the distance of about ten microns which separates the microinductor from the substrate in the processes of the prior art.

It will also be noted that the electrolytic copper deposition involves two separate steps, namely firstly a first step for filling the via, thereby firstly allowing the copper to be increased up to the level of the lower plane of the inductive microcomponent and then a second step of electrolytic deposition of copper which forms, simultaneously, the turns of the inductive component and the region in which the turns are connected to the via already filled in the previous deposition step.

Consequently, separating these two copper deposition steps ensures deposition homogeneity favourable to regularity of the shape of the turns and therefore the quality of the electrical performance and the reproducibility of the process.

After each of these electrolytic copper deposition steps, a planarization operation is carried out, which makes it possible to obtain an optimum surface finish and to remove those regions of the copper diffusion barrier layer and of the initiating layer which lie outside the regions where the copper has to remain visible for the subsequent operations.

It will also be noted that this process may be used on various types of substrate. Thus, in a first family of applications, the process may be used on a semiconductor substrate and especially a substrate which has been functionalized beforehand in order to form an integrated circuit.

In other types of applications, the substrate may be a specific one, such as an amorphous substrate of the glass or quartz type, or more generally a substrate having electrical, optical or magnetic properties suitable for certain applications.

In practice, the material of low relative permittivity which is deposited on the substrate may be benzocyclobutene (BCB) or else a similar material whose relative permittivity is typically less than 3.

In practice, the thickness of this layer of material of low relative permittivity may be between 10 and 40 micrometres, it preferably being close to 20 micrometres.

The thickness of this layer (or of these layers when there are several of them stacked together) defines substantially the distance between the inductive component and the substrate. This distance, combined with the relative permittivity of the material of this layer, defines the parasitic capacitance existing between the inductive component and the substrate, it being highly desirable to minimize this capacitance.

In practice, the material used to form the hard mask on top of the BCB may be chosen from the group comprising: SiC, SiN, Si₃N₄, SiO₂, SiOC, SiON, WSi₂, Y₂O₃, taken separately or in combination. These materials have properties ensuring good compatibility with BCB, especially strong adhesion as hard mask on the surface of the BCB. These materials have mechanical properties suitable for their use in masking. Moreover, since this layer is used as a hard mask for the purpose of etching the vias, a high selectivity of the etching of BCB with respect to these materials is required, so as to avoid any overetching of the BCB, and thus obtain the desired profiles without delamination.

This is because the stresses between the BCB and the hard mask could be transmitted right to the substrate and possibly cause the latter to fracture. These phenomena involving excessively high stresses are especially observed in those processes of the prior art which use thick layers of certain metals to produce the hard mask on top of a BCB layer, having as a consequence the risk of poor adhesion.

According to another feature of the invention, a layer forming a copper diffusion barrier is deposited on top of the hard mask. This barrier layer allows the subjacent layer to be isolated from the copper which will be subsequently deposited, especially in the form of an initiating layer. This characteristic barrier layer prevents copper from migrating through the layer of low relative permittivity, which would have the effect of increasing this permittivity and therefore of increasing the parasitic capacitance between the inductive microcomponent and the substrate and of creating sources of defectiveness. This barrier layer also prevents the copper from migrating into the substrate, which would have prejudicial consequences on the quality or the operation of the integrated circuit.

It should be pointed out that the diffusion barrier layer is deposited in two separate steps. The layer deposited during the first step forms a barrier with respect to the copper in the via. The second step allows this barrier to be deposited in such a way that it covers the lateral faces and lower face of the various turns and conducting features which will subsequently be produced. This second barrier layer prevents the migration of copper from the turns into the upper resin layer.

In practice, the barrier layer may be made of tungsten or of a material chosen from the group comprising TiW, Ti, TiN, Ta, TaN, WN, Re, Cr, Os, Mo and Ru. These materials may be used separately or in combination.

In practice, the diffusion barrier layer may advantageously have a thickness of between 100 and 400 Å.

According to another feature of the invention, the process may include a step of enriching the copper initiating layer. This initiating layer acts as an electrode for the subsequent electrolytic copper deposition steps.

It may prove useful under certain conditions to improve the regularity and the morphology, the oxidation state of the copper and the roughness of this initiating layer, as well as the lack of nucleation sites in the latter. This initiating layer is deposited physico-chemically and more particularly by the technique called sputtering and, according to its variant, sputtering of “metal ionized with a plasma source” or IMP. In this case, a process involves a step of enriching this initiating layer by immersing the initiating layer in an electrolyte solution. This solution, containing copper salts, is used to deposit copper in the possible spaces existing between the islands of copper deposited beforehand when producing the initiating layer. This enriching step therefore ensures that this initiating layer is smoothed out so as to improve the subsequent electrolytic deposition.

In practice, annealing steps may advantageously then be carried out, allowing the size of the copper crystals deposited during the electrolytic deposition steps to be increased. This annealing step, typically one in which the component is exposed to a temperature of between 150 and 400° C. for a time of a few minutes, ensures crystalline uniformity of the copper deposited and therefore the homogeneity and conductivity of the copper which will form the turns of the inductive component. The electrical properties of the component are thus improved by reducing the number of singularities which may be the source of resistive points or points of mechanical weakness.

In practice, a decontamination step may advantageously be carried out in order to remove the copper liable to migrate into the substrate, especially at the lateral and posterior faces of the substrate as well as around its circumference. This is because when the component is exposed to a solution containing soluble copper salts, it is recommended to remove any excess copper deposited since, when this metal is deposited using electrolytic techniques and using a specific current distribution between the cathode and the anode, it is generally observed that excess copper is deposited around the circumference of the substrate. Moreover, the mass transfer and convection process, which is at the basis of the electrolytic technique of depositing the element copper, results, on the lateral or posterior faces of the substrate, in a possible flux and diffusion over certain regions of the substrate. To avoid their possible migration into the substrate, it is recommended to use this step. This decontamination step may also allow the shape of the regions in which the electrolytic copper deposition takes place, especially at the edges of the turns, to be regularized.

In practice, this decontamination step may take place after one or other of the two electrolytic deposition steps.

According to other features of the invention, certain chemical cleaning steps may be carried out using a chemical which is not corrosive with respect to copper. These cleaning steps may be carried out after the electrolytic copper deposition and after the step of depositing the copper initiating layer or of depositing the copper diffusion barrier layer.

It is also possible to deposit a passivation layer, typically obtained by firstly depositing a nickel layer on the copper turns and secondly by covering this layer by depositing a gold layer. This passivation layer may also be obtained by the non-selective deposition of a chromium layer, followed by the etching of this layer away from the turns and conducting features.

The invention also relates to an electronic component able to be produced by the process explained above. Such a component incorporates an inductive micro-component placed on a substrate and connected to the latter by at least one metal contact.

This component comprises:

at least one superposition of a layer of material having a low relative permittivity and of a hard mask layer, the first layer of material having a low relative permittivity resting on the upper face of the substrate;

a number of defined metal turns on top of the superposition of layers of material having a low relative permittivity; and

a copper diffusion barrier layer present on the lower and lateral faces of the metal turns.

### BRIEF DESCRIPTION OF THE DRAWINGS

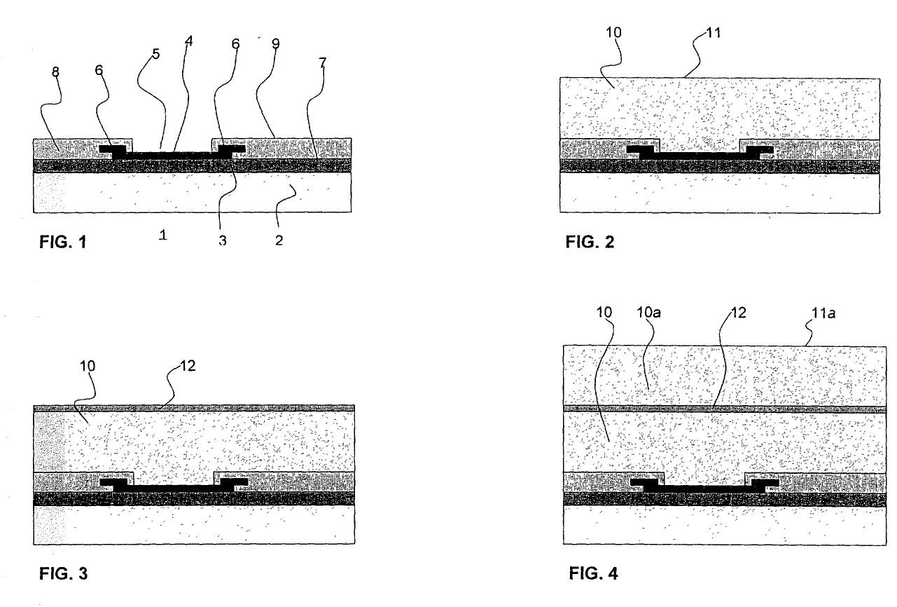

The manner in which the invention is realized and the advantages which arise therefrom will become clearly apparent from the description of the embodiment example which follows, supported by the appended FIGS. 1 to 24, which are cross-sectional representations, in the region of a connection contact, of the substrate and of the various layers which are progressively deposited in the steps of the process. The thicknesses of the various layers illustrated in the figures are given so as to allow the invention to be understood but are not always in proportion to the actual thicknesses and dimensions.

### MANNER OF REALIZING THE INVENTION

As already mentioned, the invention relates to a process allowing inductive microcomponents to be produced on a substrate. Tn the example illustrated in the figures, the substrate (1) used is a substrate which has been pretreated so as to form an integrated circuit. However, other different substrates may be used, such as, in particular, substrates based on quartz or glass.

Thus, such a substrate (1) as illustrated in FIG. 1 includes the upper level (2) of the actual integrated circuit, said level being surmounted by a doped substrate layer (3).

In the figure shown, the substrate (1) also includes a metal contact (4) made of aluminium, an aluminium-based alloy or copper, the upper face (5) of which is accessible. The edges (6) of this metal contact and the upper face (7) of the doped layer are covered with a passivation layer (8).

The process according to the invention may link up the various steps described below, it being understood that some of them may be carried out in a different manner, while still obtaining similar results. Certain steps may also be considered as useful but not indispensable, and may therefore in this regard be omitted without departing from the scope of the invention.

Step 1

The first step consists in cleaning the upper face (5) of the metal connection contact (4) and the passivation layer (8) deposited on the substrate. This cleaning is carried out by a wet chemical route.

Step 2

As illustrated in FIG. 2, the process continues with the deposition of a layer (10) of benzocyclobutene (BCB) or any equivalent material possessing a relative permittivity of less than 3. This deposition is carried out by a process called “spin-on deposition”. The thickness deposited is about 20 micrometres.

Step 3

The process continues with the cleaning of the upper face (11) of the BCB layer (10). This cleaning, carried out with a suitable solution, ensures that the upper face (11) of the BCB layer (10) is clean and prepared.

Step 4

As illustrated in FIG. 3, the process continues with the deposition of a layer (12) forming a hard mask on top of the BCB layer (10). This layer (12) has a thickness greater than 200 Å. The material employed is preferably silicon carbide (SiC), but it could also be SiOC, SiN, Si₃N₄, SiON, SiO₄, SiO₂, WSi₂ or Y₂O₃ or any other material, provided that the etching selectivity with respect to the material of the lower layer is at least 10:1. This hard mask layer (12) may be deposited by a PECVD (Plasma-Enhanced Chemical Vapour Deposition) process.

Step 5

The process continues with the deposition of a new layer (10a) of BCB, in the same way as carried out in step 2.

Step 6

The process continues with the cleaning of the upper face (11a) of the BCB layer (10a) as in step 3 described above.

Step 7

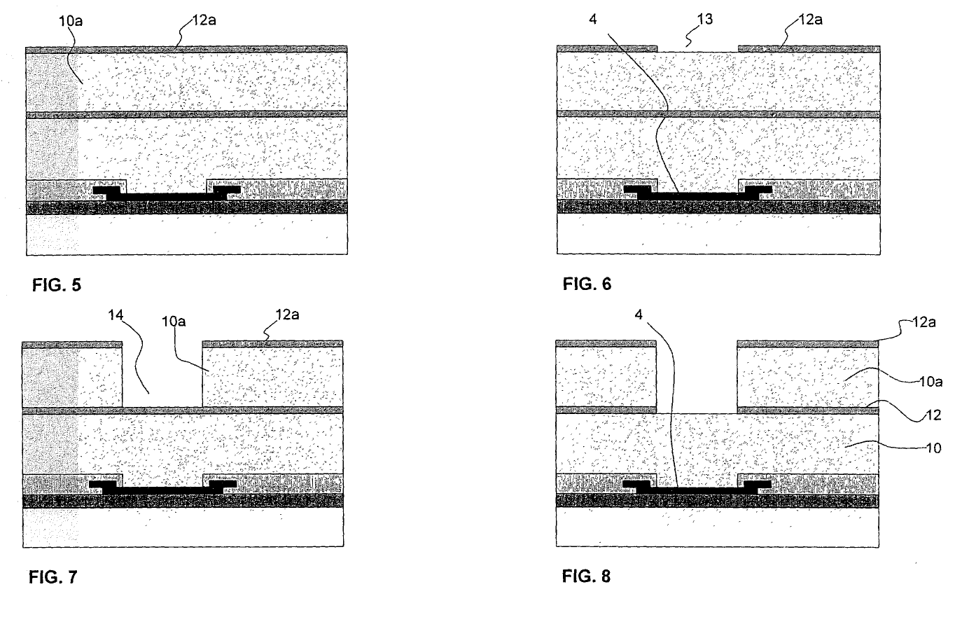

As illustrated in FIG. 5, a new layer (12a) forming the hard mask is deposited on top of the BCB layer (10a). The operating method is the same as that described above in the case of step 4.

Thereafter, it is possible to deposit, as many times as necessary, new BCB layers surmounted by a hard mask. This sequence of steps allows the distance between the substrate and the future inductive component to be increased. In the embodiment illustrated in the figures, the component has only two BCB layers, but it goes without saying that the invention covers variants in which the number of BCB layers is greater, for example up to 5. It is also possible to deposit only a single BCB layer and only a single hard mask, and thus omit steps 5 to 7.

Step 8

An aperture (13) is then made in the hard mask (12a), as illustrated in FIG. 6, by a lithography process and a suitable wet chemical etching process using a solution such as one based on hypophosphoric acid at a temperature of 180° C., if the hard mask is composed of silicon nitride, or a dry plasma etching process using a reactive fluorinated gas, such as CF₄:H₂ for example.

Step 9

The process then continues as illustrated in FIG. 7 with the isotropic etching of the BCB layer (10a) vertically in line with the metal connection contact (4) so as to form the upper part of the via (14) . The BCB layer (10a) may especially be etched by the use of a gas mixture such as an Ar/CF₄/O₂ mixture or else by a radiofrequency plasma using other reactants.

Step 10

The process then continues as illustrated in FIG. 8, with the etching of the hard mask layer (12) in a manner described in step 8.

Step 11

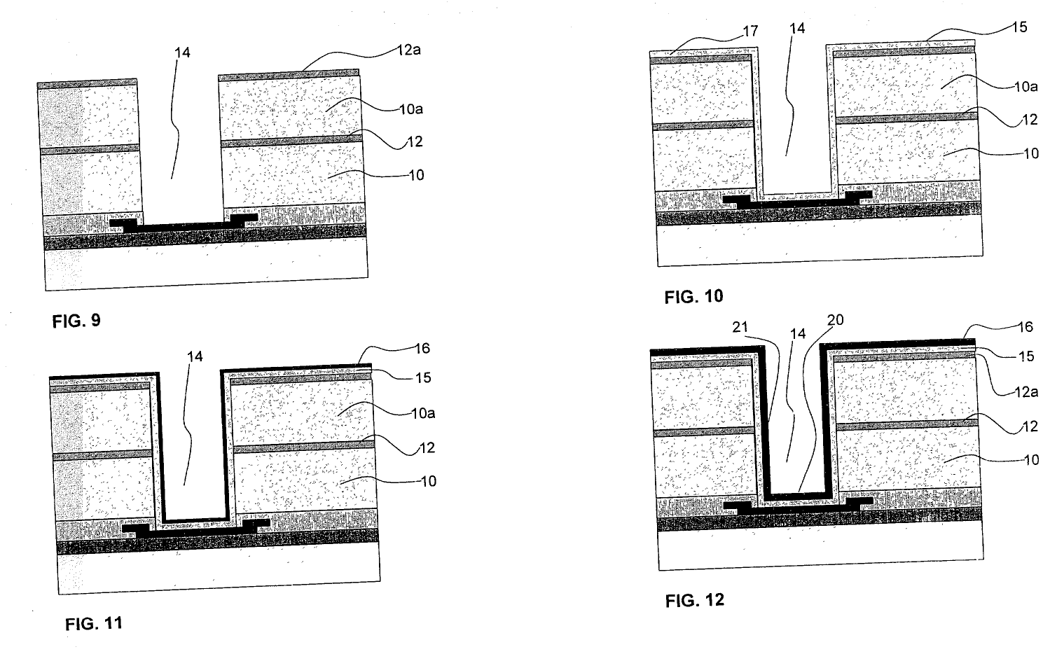

The process then continues as illustrated in FIG. 9 with the etching of the BCB layer (10) in the manner described in step 9.

Step 12

The process then continues with the cleaning of the via (14) using various processes. Thus, this may be chemical cleaning using a non-corrosive semi-aqueous mixture. It may also be dry cleaning using an argon plasma, with a power of around 300 kilowatts, by exposing the region (14) to radiofrequency waves for a time of about one minute and at room temperature.

Step 13

As illustrated in FIG. 10, the process continues with the deposition of a copper diffusion barrier layer (15). This layer (15) covers the bottom and the walls of the via (14), as well as the visible upper faces (17). This layer (15) is preferably made of a titanium-tungsten alloy, or a superposition of titanium and titanium nitride, or else tantalum and tantalum nitride. This layer (15) may also be made of tungsten nitride or by a single layer of tungsten, molybdenum, osmium or ruthenium. This layer (15), having a thickness of between 200 and 400 Å, may be deposited by various techniques, and especially by sputtering, which process is also known by the abbreviation IMP-PVD (Ion Metal Plasma - Physical Vapour Deposition), or by chemical vapour deposition techniques such as those known as CVD (Chemical Vapour Deposition) and ALD (Atomic Layer Deposition.

Other processes, such as especially those known as IMP (Ion Metal Plasma) may also be used.

Step 14

As illustrated in FIG. 11, the process then continues with a deposition of a copper initiating layer (16). This initiating layer (16) may be deposited by various techniques, and especially by sputtering, which process is also known by the abbreviation IMP-PVD (Ion Metal Plasma—Physical Vapour Deposition) or by chemical vapour deposition techniques such as those known as CVD (Chemical Vapour Deposition) and ALD (Atomic Layer Deposition). The layer thus obtained typically has a thickness of between 500 and 2000 Å.

Step 15

The process continues, as illustrated in FIG. 12, with a step of electrolytically enriching the initiating layer (16). A solution of copper salts, such as CuSO₄5H₂O, dissolved in a solvent such as sulphuric acid, may be used. This solution also contains a base such as sodium hydroxide and a monodentate chelate such as glycol acid, a buffer agent such as CAPS (or, in expanded form, 3-(cyclohexylamino)-1-propanesulphonic acid) and a glycol ether, using either a DC current or an AC current. An autocatalytic deposit comprising a reducing agent, such as dimethylamineborane, may also be produced, substituting the electrolytic current.

This enriching step is used to fill the spaces between the islands of copper which had been deposited beforehand in order to form the initiating layer. The surface of the initiating layer (16) is therefore smoothed in this way, thereby favouring the subsequent electrolytic deposition step. This step is used to increase the thickness of the initiating layer within the via, and more particularly on the inside faces (21) and at the bottom (20) of the via (14).

Step 16

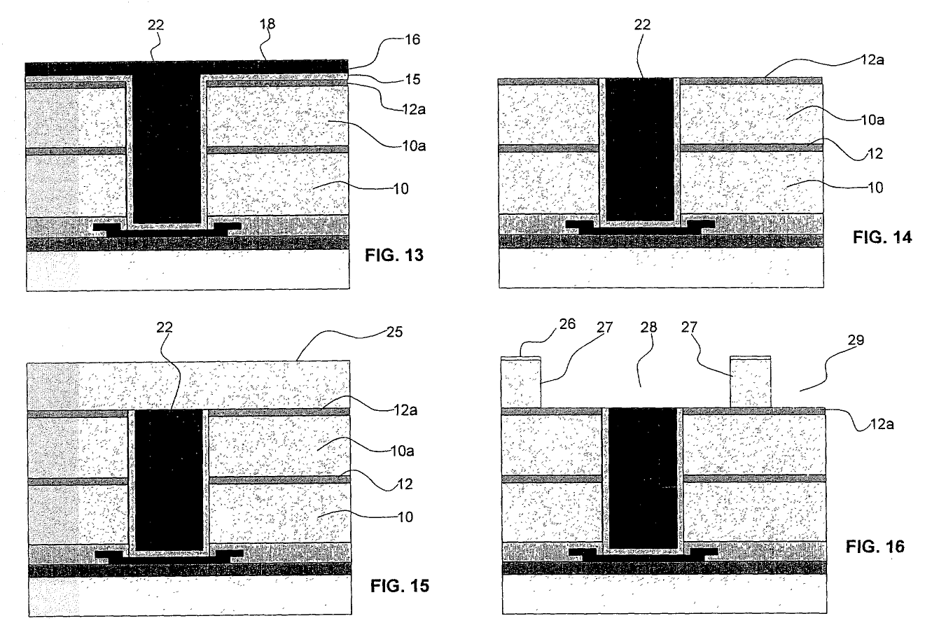

Next, as illustrated in FIG. 13, copper is deposited electrolytically, using a technique called “bottom-up growth” corresponding to a particular technique when the microstructure is a damascene, and also known as “bottom-up damascene superfilling”. This step makes it possible to fill the volume (22) of the via (14) and to cover the upper faces (18) of the component on top of the initiating layer (16).

This step uses an electrolyte solution whose formulation is defined in order to obtain the optimum copper quality, namely a resistivity before grain growth during annealing of between 1.9 μΩ.cm and 2.3 μΩ.cm and preferably between 2 μΩ.cm and 2.15 μΩ.cm.

The solutions used may be, for example, those sold under the name “Cu VIAFORM” by Enthone or “Cu GLEAM ELECTRODEPOSIT 6000” by Shipley.

Step 17

The process may then continue with a decontamination step for removing any trace of copper which might be liable to migrate into the substrate or into any other part on which copper ions could have been deposited. This decontamination step makes it possible in particular to clean the rear of the substrate and the peripheral regions of the substrate. By these peripheral regions is meant the lateral faces of the substrate which are perpendicular to the principal plane of the substrate, together with those edges of the substrate on which excess copper deposits could have been built up.

This decontamination step is carried out by a wet chemical method by means of a tool allowing the substrate to be treated face by face, using a solution containing, for example, a mixture of hydrogen peroxide and sulphuric acid.

Step 18

The process then continues with a so-called annealing step for reorganizing the crystalline structure of the copper (22) deposited in the via, by making the individual crystalline grains grow in size. This step uses a technique known as RTP (Rapid Thermal Processing) during which the component is subjected to a temperature of around 150 to 400° C., preferably close to 300° C., for a time of 10 seconds to 30 minutes and preferably around 5 minutes. The component is maintained in an atmosphere of an inert gas or else in a vacuum, preventing any oxidation and diffusion of oxygen into the crystalline medium of the copper.

The parameters are carefully defined in order to obtain the optimum copper quality, namely a resistivity after grain growth of between 1.72 μΩ.cm and 1.82 μΩ.cm.

Step 19

A process then continues as illustrated in FIG. 14 with a planarization operation. This planarization is carried out by a CMP (chemical-mechanical polishing) technique. More specifically, this is a CMP operation using a belt machine, such as especially that known by the name “TERES” from Lam Research.

This planarization is used to remove the copper layer (18) which was deposited electrolytically, together with the subjacent initiating layer (16) and the barrier layer (15) lying on top of the hard mask (12a). The use of a “belt” CMP machine makes it possible to limit the stresses exerted on the upper face of the component. This planarization step links together two separate steps and is based on a chemical surface reaction. The first CMP step uses abrasion on a hard belt fabric such as a cured foam fabric IC1000 offered by the company Rodel. The chemical solution is an aqueous mixture allowing copper to be selectively etched with respect to the barrier layer by a variable formulation. This mixture contains an oxidizing agent, such as hydrogen peroxide, a specific solvent, such as triazole and tetrazole derivatives, chelates and reaction catalysts, such as Rochelle salts or ammonium citrates, a corrosion inhibitor, such as BTA, water and grit particles composed of alumina or of cerium oxide, or iron kyanites. The function of this first chemical step is to etch the copper deposited in excess on top of the damascene microstructure at high rate of abrasion, of between 150 and 200 nanometres per minute.

The second CMP step uses a softer belt fabric, such as IC400 from Rodel. The aqueous chemical solution is used to etch the barrier layer and the copper, smoothing it by a chemical action using, inter alia, suspended particles of the silica Klebosol or cerium oxide type, acting as grit, and an aqueous phase composed of organic amine compounds such as diethylenetetramine, a corrosion inhibitor, such as BTA (benzotriazole) and, as solvent, water and IPA (isopropyl alcohol). However, other solutions corresponding to the criteria of the present invention already exist in commercial form. Mention may be made, in particular, of the chemical solutions and the grit in the MicroPlanar™ CMP9000™ series proposed by EKC Technology (based at 2520 Barrington Court Hayward, Calif. 94545-1163).

Step 20

The process then continues with a cleaning step carried out on the upper face of the polished component. This cleaning makes it possible to remove the polishing residues composed of colloids based on copper oxide complexes, without having to etch the upper copper layer which has just been polished, and without causing corrosion phenomena by a solution with a defined pH. Chemical solutions have been proposed by manufacturers such as EKC Technology, such as the commercial product known by the name “MicroPlanar™ PCMP5000™ series” or aqueous chemical solutions composed of a monodentate or polydentate chelate, such as alkaline gluconate, citrate or oxilate ions, a fluorinated acid, such as hydrofluoric acid and a corrosion inhibitor, such as an imidazole derivative.

Step 21

The process then continues, as illustrated in FIG. 15, with the deposition of an upper resin layer (25). This layer (25) is made of a material having a low relative permittivity, such as especially BCB or preferably a polyimide. This material is deposited using a spin-on deposition technique. The thickness of the upper resin (25) thus deposited is of the order of magnitude of the height of the turns of the inductive microcomponent. It is possible to use, for example, a polyimide chosen from the family of photosensitive polyimides such as PI-2771, PI-2727 or PI-2730 sold by DuPont de Nemours. Other polyimides such as those sold under the references PI-2600 Series, PI2545 Series by DuPont Nemours may be employed, if a photolithography step and a wet or dry (using a plasma) etching process are carried out in order to define the topography in the polyimide.

Step 22

The process then continues with the deposition of a lithography layer (26) on top of the upper resin layer. This resin is then irradiated to define the forms of the future turns and other conducting features.

Step 23

The process then continues with the etching of the upper resin layer (25) in order to obtain, as illustrated in FIG. 16, various channels (28, 29) which are separated by those regions (23) of the upper resin which have not been etched.

Step 24

The process then continues with a cleaning step by applying a solution which is not corrosive to copper, so as to remove all the residues produced by the lithography step. This step makes it possible to clean the upper face of the copper (22) filling the via, and to remove those portions (26) of lithography resin lying on top of the regions (27) of upper resin (25) . The cleaning is carried out by chemical means, using solutions containing aminated components and molecules which are not corrosive to copper, such as benzotriazole, or components such as ACT 970 sold by Ashland.

Step 25

The process then continues with the deposition of a copper diffusion barrier layer (35), in the same way as described in the case of Step 13 above.

Step 26

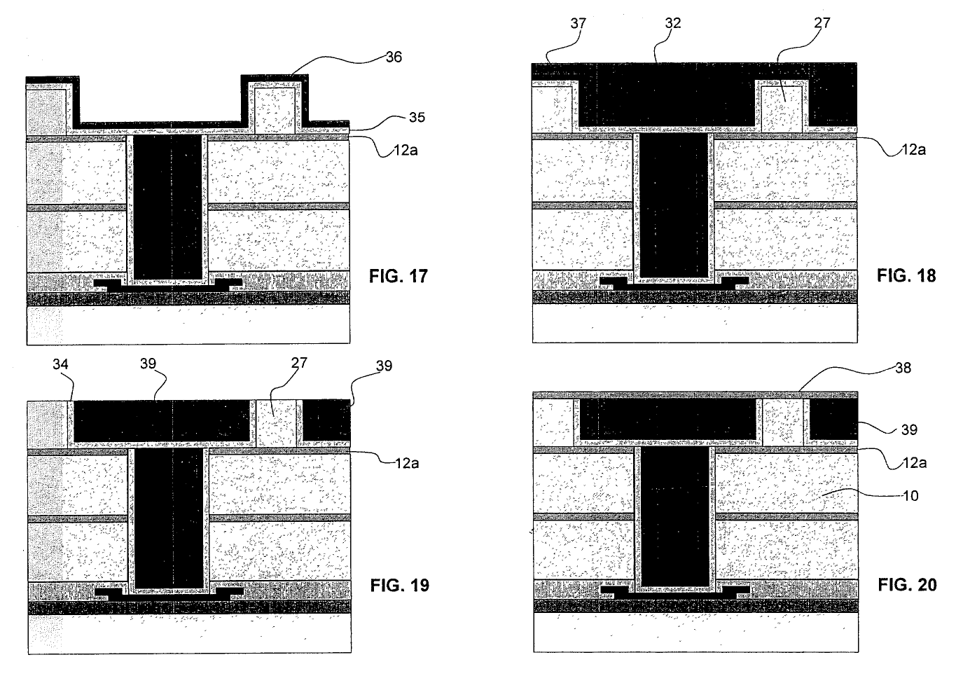

The process then continues as illustrated in FIG. 17 with the deposition of a copper initiating layer (36) in the same way as that described in the case of Step 14 above. This initiating layer (36) is then enriched in the same way as described in Step 15 above.

Step 27

The process then continues as illustrated in FIG. 18 with the deposition of a copper layer (32) in the damascene microstructure, as described in Step 16 above.

Step 28

The process then continues with a decontamination step similar to that described in Step 17 above.

Step 29

The process then continues with an annealing step as described in Step 18 above.

Step 30

The process then continues, as illustrated in FIG. 19, with a planarization operation, using a belt CMP machine, in the same way as in Step 19 described above. This planarization is carried out until the copper layer (37) lying on top of the remaining regions (27) of the upper resin is removed. This step also removes the initiating layer (36) and the copper diffusion barrier layer (35) which is on top of these remaining regions (27).

The presence of the copper diffusion barrier layer (35) on the vertical regions (34) separating the turns and the upper resin avoids any problem of copper migrating into the polyimide, which phenomenon would tend to occur in the annealing steps, during which the component is subjected to a high temperature.

Step 31

The process then continues as in the case of Step 20 with the cleaning of the upper face of the component.

Step 32

The process then continues, as illustrated in FIG. 20, with the deposition by sputtering of a chromium layer (38). This chromium layer (38), having a thickness of between 100 and 500 Å, and preferably in the region of 250 Å, acts as a protection barrier for the copper turns (39) that it covers.

This chromium layer (38) exhibits good adhesion to the polyimide forming the remaining regions (27) of the upper resin (25). This chromium layer (38) also acts as an oxygen barrier.

Step 33

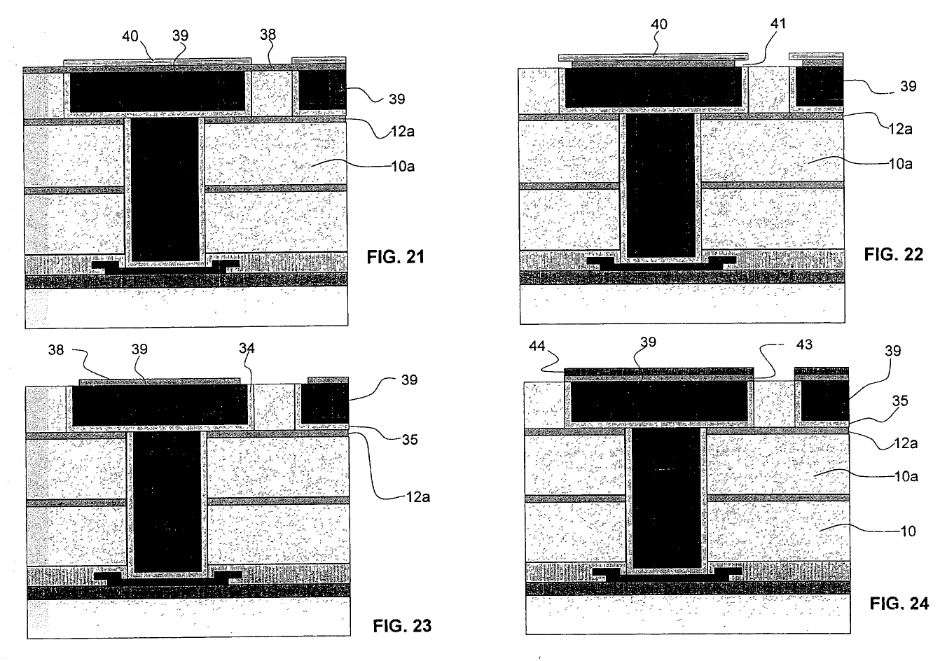

The process then continues, as illustrated in FIG. 21, with the deposition of a lithographic etching mask (40) on top of the chromium layer (38), vertically in line with the turns (39) and with possible conducting features.

Step 34

The process then continues, as illustrated in FIG. 22, with a wet etching step carried out on the chromium layer (38). Since this etching is anisotropic, overetching phenomena (41) along the border of the features of the lithography resin (40) are observed.

Step 35

The process then continues, as illustrated in FIG. 23, with the removal of the resin (40) covering the chromium layer (38).

Step 36

The process then continues with a cleaning step, which is not corrosive to copper, identical to that described in Steps 12 and 24.

It should be noted that the deposition of the chromium passivation layer (38) forming the subject of steps 34 and 35 may be replaced, as illustrated in FIG. 24, with the succession of selective deposition of a nickel layer (43) and of a gold layer (44), only on top of the turns (39) and of the conducting features.

It is apparent from the foregoing that the process according to the invention makes it possible to obtain inductive microcomponents which have a very high quality factor because of the great distance between the substrate and the principal plane of the inductive microcomponent. Typically, the quality factors obtained are greater than 50 at a frequency of the order of 2 gigahertz with topologies of the turns constituting the inductive microcomponent, the feature of which is defined by a turn width of less than 3 micrometres and height of greater than 10 micrometres, and an inter-turn distance which may be less than 3 micrometres.

By splitting the electrolytic copper deposition into two separate steps it is possible to optimize the regularity of the shape of the various turns, without increasing the manufacturing costs, and therefore to make the process very reproducible, resulting in the production of the microcomponent having electrical characteristics close to those defined during the design stage.

It is also possible by means of this process to produce various conducting features serving as conducting re-routing tracks making it possible to interconnect, by a spatial offset, interconnection pads and metalization levels of the transistors. This is obtained while limiting the resistance and the capacitive effect and by increasing the resistance to electromigration of the copper atoms in the lines and interconnection paths.

Moreover, the process according to the invention makes it possible to control the interfaces between the various layers of material deposited, with as a consequence a substantial improvement in the performance of the device and fewer sources of defectiveness.

1. Process for fabricating an electronic component, incorporating an inductive microcomponent placed on top of a substrate (1) and connected to the latter by at least one metal contact (4), characterized in that it comprises the following steps, consisting successively in:
a) depositing on the substrate at least one stack of a layer (10, 10a) of a material having a low relative permittivity and of a layer (12, 12a) forming a hard mask;
b) making an aperture (13) in the hard mask layer (12a) placed in the upper position, vertically in line with the metal contacts (4);
c) etching the layer or layers (10, 10a) of material having a low relative permittivity and the subjacent hard mask layer or layers down to the metal contact (a), in order to form a via (14);
d) depositing a layer (15) forming a copper diffusion barrier;
e) depositing a copper initiating layer (16);
f) depositing, electrolytically, a copper layer (32) filling the via and covering the initiating layer (16);
g) planarizing the upper face until the upper hard mask layer (12a) is exposed;
h) depositing an upper resin layer (25) formed from a material having a low relative permittivity;
i) etching the resin layer (25) in order to form the channels (28, 29) defining the turns of the inductive microcomponent and of possible other conducting features;
j) depositing a copper diffusion barrier layer (35);
k) depositing a copper initiating layer (36);
l) depositing copper (32) electrolytically at least on top of the channels (28, 29) thus etched;
m) planarizing until the upper resin layer (25) is revealed.

2. Process according to claim 1, characterized in that it also includes a step of depositing a passivation layer on top of the copper turns.

3. Process according to claim 2, characterized in that the passivation layer is obtained by non-selective deposition of a chromium layer (38) followed by etching of this layer away from the turns (39) and the conducting features.

4. Process according to claim 2, characterized in that the passivation layer is obtained by the selective deposition of a nickel layer (43) on top of the turns and the conducting features, and then by selective deposition of a gold layer (44).

5. Process according to claim 1, characterized in that the substrate (1) is a semiconductor substrate forming an integrated circuit.

6. Process according to claim 1, characterized in that the substrate is an amorphous substrate of the glass or quartz type.

7. Process according to claim 1, characterized in that the material (10, 10a) of low relative permittivity deposited on the substrate is benzocyclobutene.

8. Process according to claim 1, characterized in that the thickness of the layer (10, 10a) of material of low relative permittivity is between 10 and 40 micrometres, preferably 20 micrometres.

9. Process according to claim 1, characterized in that the material used for the layer (12, 12a) forming the hard mask is chosen from the group comprising: SiC, SiN, Si₃N₄, SiO₂, SiOC, SiON, WSi₂, Y₂O₃, taken separately or in combination.

10. Process according to claim 1, characterized in that the material used for the copper diffusion barrier layer (15, 35) is chosen from the group comprising TiW, Ti, TiN, Ta, TaN, W, WN, Re, Cr, Os, Mo, Ru, taken separately or in combination.

11. Process according to claim 1, characterized in that the thickness of the copper diffusion barrier layer (15, 35) is between 100 and 400 Å.

12. Process according to claim 1, characterized in that it includes a step of enriching the copper initiating layer (16, 36).

13. Process according to claim 1, characterized in that it includes an annealing step intended to increase the size of the copper crystals deposited during the electrolytic deposition steps.

14. Process according to claim 1, characterized in that it includes a decontamination step to remove the copper liable to migrate into the substrate (1), especially at the lateral faces of the substrate.

15. Process according to claim 14, characterized in that the decontamination step takes place after at least one of the electrolytic deposition steps.

16. Process according to claim 1, characterized in that it includes at least one chemical cleaning step, using a chemical which is not corrosive with respect to copper, after the electrolytic copper deposition steps and/or after the steps of etching the copper initiating layer (16, 36) and/or the copper diffusion barrier layer (15, 35).

17. Process according to claim 1, characterized in that the deposition of copper intended to form the turns (39) is carried out so as to give a copper thickness of greater than 10 micrometres.

18. Electronic component, incorporating an inductive microcomponent placed on top of a substrate (1) and connected to the latter by at least one metal contact (4), characterized in that it comprises:
at least one superposition of a layer (10, 10a) of material having a low relative permittivity and of a hard mask layer, the first layer (10) of material having a low relative permittivity resting on the upper face of the substrate (1);
a number of defined metal turns (39) on top of the superposition of layers (10, 10a) of material having a low relative permittivity; and
a copper diffusion barrier layer (35) present on the lower and lateral faces of the metal turns (39).

19. Component according to claim 18, characterized in that the substrate is a semiconductor substrate forming an integrated circuit.

20. Component according to claim 18, characterized in that the substrate is an amorphous substrate of the glass or quartz type.

21. Component according to claim 18, characterized in that the material (10, 10a) of low relative permittivity deposited on the substrate is benzocyclobutene.

22. Component according to claim 21, characterized in that the thickness of the layer (10, 10a) of material of low relative permittivity is between 10 and 40 micrometres, preferably close to 20 micrometres.

23. Component according to claim 18, characterized in that the material used for the copper diffusion barrier layer (15, 35) is chosen from the group comprising TiW, Ti, TiN, Ta, TaN, Mo, W, WN, Re, Cr, Os and Ru, taken separately or in combination.

24. Component according to claim 18, characterized in that the thickness of the copper diffusion barrier layer (15, 35) is between 100 and 400 Å.

25. Component according to claim 18, characterized in that it includes a passivation layer present on the copper turns, the said layer typically including nickel (43) and gold (44), or chromium (38).

26. Component according to claim 18, characterized in that the thickness of the turns (39) is greater than 10 micrometres.

27. Component according to claim 18, characterized in that the width of the turns (39) is less than 3 micrometres.

28. Component according to claim 18, characterized in that the distance between the turns (39) is less than 3 micrometres.

29. Component according to claim 18, characterized in that the quality factor of the inductive microcomponent is greater than 50 at 2 gigahertz.

30. Component according to claim 18, characterized in that the resistivity of the turns is between 1.72 μΩ.cm and 1.82 μΩ.cm.
